(19) United States
(12) Patent Application Publication
(10) Pub. No.: US 2015/0029723 A1
(43) Pub. Date: Jan. 29, 2015

(54) LIGHT-EMITTING DIODE PACKAGE STRUCTURE AND LIGHT-EMITTING DIODE LIGHT BULB

(71) Applicant: LEXTAR ELECTRONICS CORPORATION, Hsinchu (TW)

(72) Inventors: Shih-Ju Lo, Taoyuan County (TW); Cheng-Ping Chang, Hsinchu County (TW); Hui-Kai Hsu, Taitung County (TW); I-Chun Lee, Hsinchu City (TW); Wen-Kai Shao, New Taipei City (TW)

(73) Assignee: LEXTAR ELECTRONICS CORPORATION, Hsinchu (TW)

(21) Appl. No.: 14/251,546

(22) Filed: Apr. 11, 2014

(30) Foreign Application Priority Data
Jul. 23, 2013 (TW) 102126224

(51) Int. Cl. H01L 27/15; F21V 1/00; H01L 33/62; F21K 99/00; H01L 33/52; H01L 33/50

(52) U.S. Cl. CPC H01L 27/15; H01L 33/52; H01L 33/50; H01L 33/62; F21K 9/50; F21V 1/00
USPC 362/293; 257/89; 362/311.02

(57) ABSTRACT

The disclosure provides a light-emitting diode (LED) package structure, including: a lead frame; at least two light-emitting diode chips having different light-emitting wavelengths disposed on the lead frame; an encapsulant disposed over the lead frame and covering the light-emitting diode chips, wherein the encapsulant has a first concave portion; and an optical glue disposed in the first concave portion, wherein the optical glue has a plurality of scattering particles to uniformly mix the lights of different wavelengths emitted by the light-emitting diode chips.

### CROSS REFERENCE TO RELATED APPLICATIONS

This application claims priority of Taiwan Patent Application No. 102126224, filed on Jul. 23, 2013, the entirety of which is incorporated by reference herein.

### BACKGROUND

1. Technical Field

The present disclosure relates to a light-emitting diode, and in particular to a light-emitting diode (LED) package structure and a light-emitting diode (LED) light bulb.

2. Description of the Related Art

The light-emitting diode (LED) is a semiconductor device. The material of the light-emitting diode chip is primarily III-V group elements, such as compound semiconductors like GaP, or GaAs. The principle of emitting light from a light-emitting diode is to convert electrical energy into light. In other words, applying electric current to the compound semiconductor and emitting energy in form of light through the combination of electron and hole to achieve the purpose of light emission. Since the light-emitting diode does not emit light by heating or discharging, the lifetime of the light-emitting diode is more than 100,000 hours and the idling time does not exist. Besides, light-emitting diode has advantages such as fast response (about 10⁻⁹ seconds), small volume, electricity saving, low contamination, high reliability, and suitability for mass production. Therefore, light-emitting diode has been used as a household electric appliance or an indicator light or light source in various equipment.

A general colored light-emitting diode package structure utilizes various combinations or configurations of at least one light-emitting diode chip which could emit a primary color (such as red, blue, or green) to mix the primary color in order to produce light of a color. For example, FIGS. 1A and 1B show a cross-sectional view and a top view of a conventional white light-emitting diode package structure 100. In FIG. 1A, the conventional white light-emitting diode package structure 100 may include a lead frame 110, a plurality of light-emitting diode chips 120B, 120R1, and 120R2, and an encapsulant 130. A surface of the lead frame 110 is a specular surface, which is used to reflect the light emitted by the light-emitting diode chips 120B, 120R1, and 120R2. The light-emitting diode chips 120B, 120R1, and 120R2 are disposed on the lead frame 110, and are electrically connected to the lead frame 110 through a bonding wire 140. Besides, the encapsulant 130 covers the light-emitting diode chips 120B, 120R1, and 120R2 and a portion of the lead frame 110, and exposes a portion of the lead frame 110 outside the encapsulant 130 for use as an external electrode. In general, in the white light-emitting diode package structure 100, the light-emitting diode chip 120B is a blue light-emitting diode chip, and the light-emitting diode chips 120R1, and 120R2 are red light-emitting diode chips. The light emitted by the blue light-emitting diode chip 120B and the red light-emitting diode chips 120R1, and 120R2 may be mixed to produce white light.

However, the conventional white light-emitting diode package structure 100 often suffers chromatic aberration problems or non-uniformity of light mixing as a result of different configurations of the light-emitting diode chips 120B, 120R1, and 120R2 or insufficient light mixing. For example, referring to FIG. 1B, the light emitted from the light-emitting region B′ of the white light-emitting diode package structure 100 near the blue light-emitting diode chip 120B contains more blue component, while the light emitted from the light-emitting region R′ of the white light-emitting diode package structure 100 near the red light-emitting diode chips 120R1, and 120R2 contains more red component.

Thus, a light-emitting diode package structure which may uniformly mix the light emitted is needed.

### SUMMARY

The disclosure provides a light-emitting diode (LED) package structure, including: a lead frame; at least two light-emitting diode chips having different light-emitting wavelengths disposed on the lead frame; an encapsulant disposed over the lead frame and covering the light-emitting diode chips, wherein the encapsulant has a first concave portion; and an optical glue disposed in the first concave portion, wherein the optical glue has a plurality of scattering particles to uniformly mix the lights of different wavelengths emitted by the light-emitting diode chips.

The disclosure also provides a light-emitting diode (LED) light bulb, including: a lamp base; a light source module disposed over the lamp base, wherein the light source module includes a light-emitting diode (LED) package structure, including: a lead frame; at least two light-emitting diode chips having different light-emitting wavelengths disposed on the lead frame; an encapsulant disposed over the lead frame and covering the light-emitting diode chips, wherein the encapsulant has a first concave portion; and a first optical glue disposed in the first concave portion, wherein the first optical glue has a plurality of first scattering particles to uniformly mix the lights of different wavelengths emitted by the light-emitting diode chips; a driving circuit disposed in the lamp base and electrically connecting the light source module; and a lampshade disposed over the lamp base and covering the light source module.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIGS. 1A and 1B are a cross-sectional view and a top view of a conventional white light-emitting diode package structure 100;

FIG. 2A is a cross-sectional view of a light-emitting diode package structure 200 in accordance with some embodiments of the present disclosure;

FIG. 2B is a cross-sectional view of a light-emitting diode package structure 300 in accordance with another embodiment of the present disclosure;

FIG. 3A is a cross-sectional view of a light-emitting diode package structure 400 in accordance with still another embodiment of the present disclosure;

FIG. 3B is a cross-sectional view of a light-emitting diode package structure 500 in accordance with another embodiment of the present disclosure;

FIG. 4 is a top perspective view of a light-emitting diode (LED) light bulb 600 in accordance with some embodiments of the present disclosure.

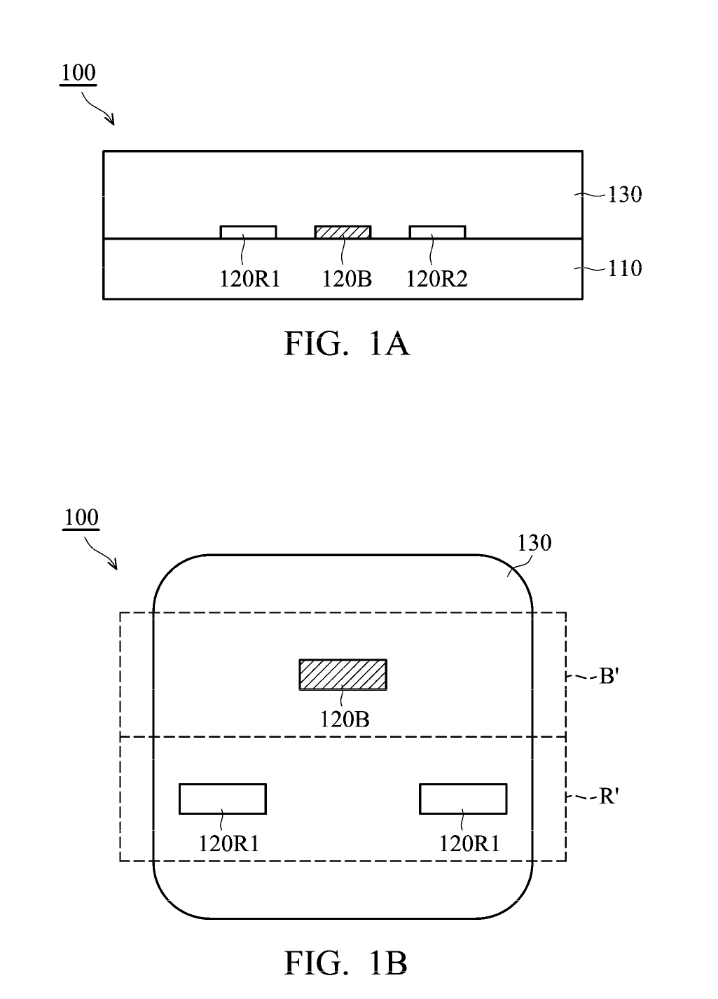

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

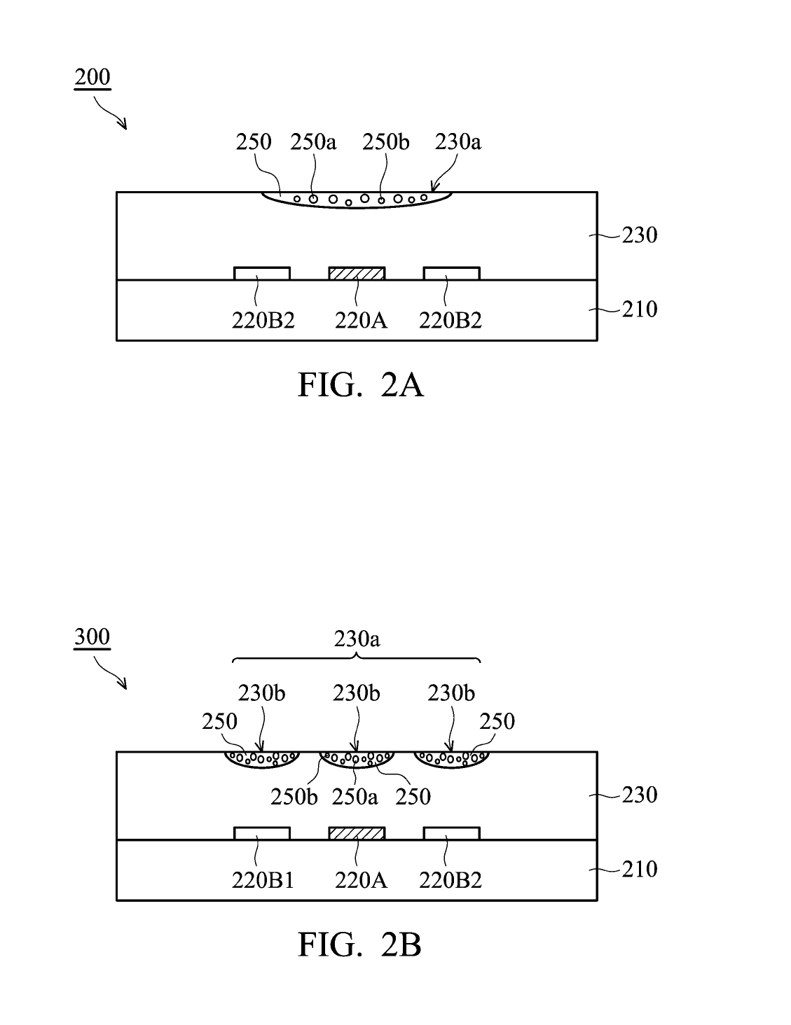

FIG. 2A is a cross-sectional view of a light-emitting diode package structure 200 in accordance with some embodiments of the present disclosure. The light-emitting diode package structure 200 may include a lead frame 210, at least two light-emitting diode chips 220A, 220B1, and 220B2 having different light-emitting wavelengths, and an encapsulant 230. In some embodiments of the present disclosure, the lead frame 210 may include, but is not limited to, a metal lead frame such as Cu lead frame or Al lead frame. Besides, metal coatings may be plated over the lead frame 210 according to the actual requirement in order to reflect the light emitted by the light-emitting diode chips 220A, 220B1, and 220B2.

The light-emitting diode chips 220A, 220B1, and 220B2 are disposed over the lead frame 210 and electrically connect to the lead frame 210. It should be noted that although FIG. 2A shows only three light-emitting diode chips, the number of the light-emitting diode chips depends on the actual design requirements. The light-emitting diode chips have at least two different light-emitting wavelengths. For example, the light-emitting diode chips 220A, 220B1, and 220B2 may be selected from two or all of the red light-emitting diode chips, blue light-emitting diode chips and green light-emitting diode chips. In one embodiment, the light-emitting diode chip 220A is a blue light-emitting diode chip, and the light-emitting diode chips 220B1, and 220B2 are red light-emitting diode chips. The light-emitting diode chips 220A, 220B1, and 220B2 may electrically connect to the lead frame 210 through a bonding wire 240. Besides, electrical connection of the light-emitting diode chips 220A, 220B1, and 220B2 may also be achieved by flip-chip technology or other die-mount processes. The encapsulant 230 covers the light-emitting diode chips 220 and a portion of the lead frame 210. The encapsulant 230 may include, but is not limited to, silicone, epoxy, thermalplastic compounds, or thermalsetting compounds. In the embodiment shown in FIG. 2A, the encapsulant 230 is formed on the lead frame 210 by compression molding.

The encapsulant 230 may further include a first concave portion 230a formed on the top surface of the encapsulant 230 and extending into the encapsulant 230. In some embodiments, the encapsulant 230 and the first concave portion 230a may be simultaneously formed by compression molding. Besides, in some other embodiments, the encapsulant 230 is formed first. Then, the first concave portion 230a is formed on the top surface of the encapsulant 230 through mechanical processing by other tools such as a drilling machine. Besides, In some embodiments of the present disclosure, the light-emitting diode package structure 200 may further include an optical glue 250 disposed in the first concave portion 230a, wherein the optical glue 250 contains a plurality of scattering particles 250a. The optical glue 250 may be epoxy, silicone, urea-formaldehyde resin, or a combination thereof. The optical glue 250 may be formed by, but is not limited to, an adhesive dripping process or any other suitable process. It should be noted that although the top surface of the optical glue 250 is coplanar with that of the encapsulant 230 in a flat-cup structure in FIG. 2A, the top surface of the optical glue 250 may be lower than that of the encapsulant 230 in a concave-cup structure, or the top surface of the optical glue 250 may be higher than that of the encapsulant 230 in a protruding-cup structure according to the actual design requirements.

The scattering particle 250a may include, but is not limited to, TiO₂, CrO₂, Al₂O₃, or a combination thereof. The diameter of the scattering particle 250a is about 0.3˜6 μm. In one embodiment, a concentration of the scattering particle 250a is about 5 vol % to 60 vol %. The present disclosure designs the first concave portion 230a on the encapsulant 230 and fills the first concave portion 230a with the optical glue 250 containing the scattering particle 250a. The light with different wavelengths emitted by the light-emitting diode chips 220A, 220B1, and 220B2 may be mixed uniformly through the optical properties of the optical glue 250 and the scattering particle 250a to eliminate the chromatic aberration problems or the non-uniformity of light mixing of the light-emitting diode package structure 100.

In some embodiments of the present disclosure, the optical glue 250 may further include a wavelength-conversion material 250b according to the design requirements. The wavelength-conversion material 250b is used to further effectively transfer the light with different wavelengths emitted by the light-emitting diode chips 220A, 220B1, and 220B2 in the light-emitting diode package structure 100. The wavelength-conversion material 250b may be phosphor or any other suitable material.

Besides, the number of concave portions 230a and optical glues 250 may be increased according to the actual requirement. Referring to FIG. 2B, which is a cross-sectional view of a light-emitting diode package structure 300 in accordance with another embodiment of the present disclosure. As shown in FIG. 2B, the structure of the light-emitting diode package structure 300 is similar to that of the light-emitting diode package structure 200 in FIG. 2A. However, the concave portion 230a of the light-emitting diode package structure 300 may further include a plurality of concave structures 230b recessed into a top surface of the encapsulant 230, wherein each of the concave structures 230b has an optical glue 250 formed therein. It should be appreciated that although FIG. 2B shows only three concave structures 230b and optical glues 250 formed therein, the number of the concave structures 230b and optical glues 250 may be changed according to actual design requirement. In some embodiments, the plurality of concave structures 230b are arranged periodically. However, in other embodiments, the plurality of concave structures 230b are arranged non-periodically.

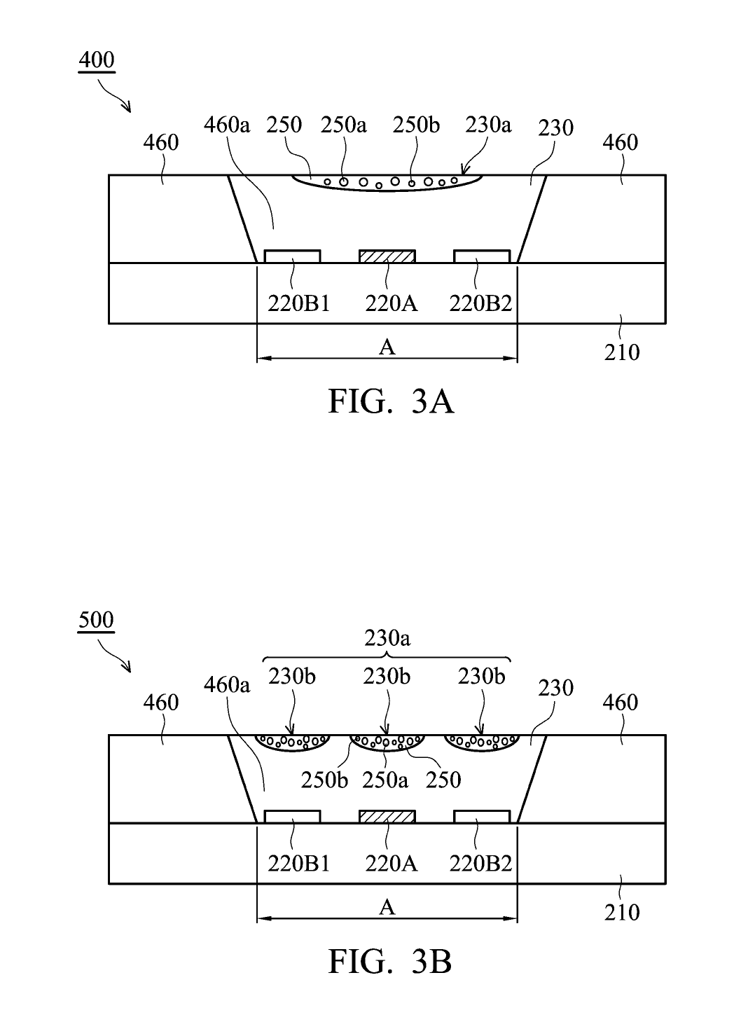

FIG. 3A is a cross-sectional view of a light-emitting diode package structure 400 in accordance with still another embodiment of the present disclosure. It is noted that like and/or corresponding elements of the light-emitting diode package structure 400 and the light-emitting diode package structure 200 are referred to by like or same reference numerals. The same or similar manufacturing process and material of the like and/or corresponding elements of the light-emitting diode package structure 400 and the light-emitting diode package structure 200 will not be described again hereinafter to avoid redundancy.

The light-emitting diode package structure 400 may include a lead frame 210, at least two light-emitting diode chips 220A, 220B1, and 220B2 having different light-emitting wavelengths, and an encapsulant 230 with a first concave portion 230a, bonding wire 240, and an optical glue 250 containing scattering particles 250a. The light-emitting diode package structure 400 may further include a main body 460 disposed over the lead frame 210. The main body 460 has a cavity 460a which concaves inward or shrinks inward gradually. The cavity 460a exposes a portion of the top surface of the lead frame 210. The portion of the top surface of the lead frame 210 exposed in the cavity 460a is defined as a die-mount region A. As shown in the Figure, light-emitting diode chips 220A, 220B1, and 220B2 are fixed at the die-mount region A of the lead frame 210, and the encapsulant 230 is formed in the cavity 460a. In this embodiment, the encapsulant 230 may be formed in the cavity 460a by an adhesive dripping process, then the concave portion 230a is formed in the encapsulant 230 through mechanical processing. Alternatively, the encapsulant 230 and the concave portion 230a may be simultaneously formed in the cavity 460a by compression molding. The optical glue 250 of the light-emitting diode package structure 400 may further include a wavelength-conversion material 250b.

Referring to FIG. 3B, which is a cross-sectional view of a light-emitting diode package structure 500 in accordance with another embodiment of the present disclosure. As shown in FIG. 3B, the structure of the light-emitting diode package structure 500 is similar to that of the light-emitting diode package structure 400 in FIG. 3A. However, the concave portion 230a of the light-emitting diode package structure 500 may further include a plurality of concave structures 230b recessed into a top surface of the encapsulant 230, wherein each of the concave structures 230b has an optical glue 250 formed therein. It should be appreciated that although FIG. 3B shows only three concave structures 230b and optical glues 250 formed therein, the number of the concave structures 230b and the optical glues 250 may be changed according to actual design requirement. In some embodiments, the plurality of concave structures 230b are arranged periodically. However, it should be noted that the configuration of the plurality of concave structures 230b is not limited to this.

The present disclosure designs at least one concave portion in the encapsulant 230 and fills the concave portion with the optical glue containing the scattering particle. The light with different wavelengths emitted by the light-emitting diode chips may be pre-mixed uniformly in the light-emitting diode package structure through the optical properties of the optical glue and the scattering particle to eliminate the chromatic aberration problems or the non-uniformity of light mixing. The present disclosure further adds the wavelength-conversion material into the optical glue to effectively transfer the light with different wavelengths emitted by the light-emitting diode chips in order to make the light emitted by the light-emitting diode package structure closer to the desired color without chromatic aberration.

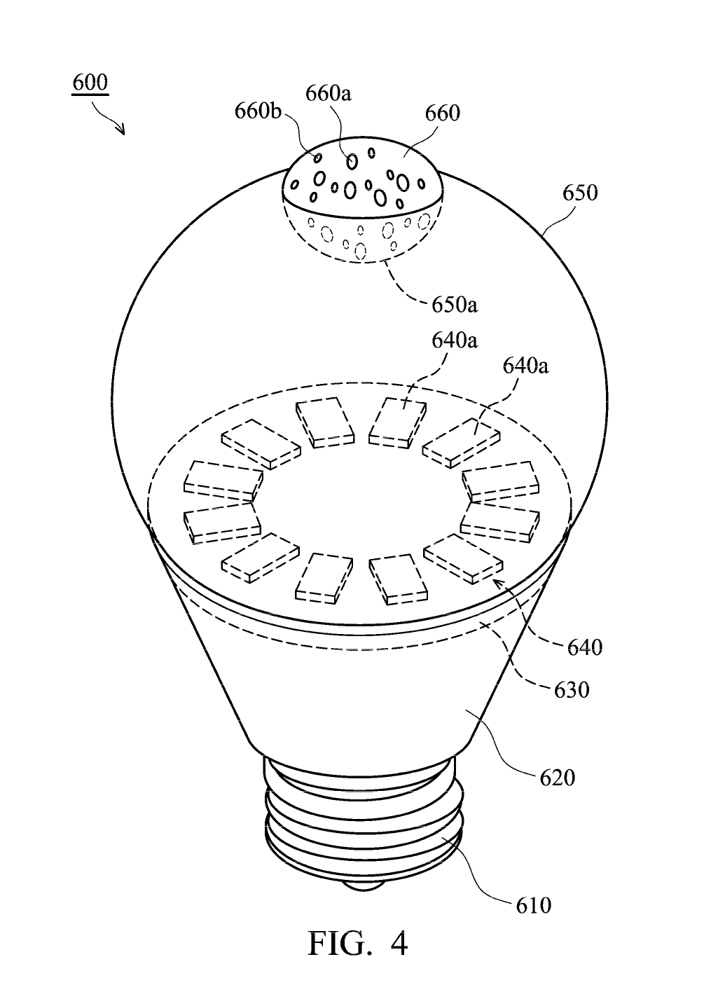

Besides, the present disclosure also provides a light-emitting diode (LED) light bulb. Referring to FIG. 4, which shows a top perspective view of a light-emitting diode (LED) light bulb 600. The light-emitting diode (LED) light bulb 600 may include a power connector 610, a lamp base 620, a driving circuit 630, a light source module 640, and a lampshade 650. The power connector 610 is used to connect to the external power source. The light source module 640 is disposed on the lamp base 620, and the driving circuit 630 is disposed in the lamp base 620 and electrically connects to the light source module 640 in order to deliver power from the external power source to the light source module 640. The light source module 640 may further include a plurality of light-emitting diode (LED) package structures 640a. It should be noted that the light-emitting diode (LED) package structure 640a may be any one of the light-emitting diode (LED) package structures shown in FIGS. 2A-3B. However, the light-emitting diode (LED) package structure 640a is not limited to those shown in FIGS. 2A-3B. The light-emitting diode (LED) package structure 640a may be any conventional light-emitting diode package structure, i.e., light-emitting diode package structure without any concave portion and optical glue. In one embodiment, all light-emitting diode (LED) package structures 640a are the same, and each light-emitting diode (LED) package structure 640a may include two or more light-emitting diode chips which are different from each other. Light emitted by the two or more different light-emitting diode (LED) chips has different wavelength. In another embodiment, the light-emitting diode (LED) package structures 640a are different from each other, and the light emitted by each light-emitting diode (LED) package structure 640a has a different color. It should be noted that the configuration of the plurality of the light-emitting diode package structures 640a is not limited to that shown in FIG. 4. The lampshade 650 is disposed over the lamp base and covers the light source module.

Besides, the lampshade 650 may further include a second concave portion 650a and a second optical glue 660 disposed in the second concave portion 650a. The second concave portion 650a is formed at a top portion of the lampshade 650 and extends from the top surface of the lampshade 650 into the lampshade 650. The second optical glue 660 contains a plurality of scattering particles 660a. The second optical glue 660 may be epoxy, silicone, urea-formaldehyde resin, or a combination thereof. The second optical glue 660 may be formed by, but is not limited to, an adhesive dripping process or any other suitable process. It should be noted that, although the top surface of the second optical glue 660 protrudes over that of the lampshade 650 in a protruding-cup structure in FIG. 4, the top surface of the second optical glue 660 may be lower than that of the lampshade 650 in a concave-cup structure, or the top surface of the second optical glue 660 may be coplanar with that of the lampshade 650 in a flat-cup structure according to the actual design requirement.

The scattering particle 660a may include TiO₂, CrO₂, Al₂O₃, or a combination thereof. In one embodiment, the diameter of the scattering particle 660a is about 0.3˜6 μm, and a concentration of the scattering particle 660a is about 5 vol % to 60 vol %. The light with different wavelengths emitted by two different light-emitting diode (LED) package structures 640a may be pre-mixed uniformly in the lampshade 650 by the second optical glue 660 having the scattering particle 660a and the chromatic aberration problems of the light-emitting diode (LED) light bulb 600 may be eliminated.

The optical glue 660 may further include a wavelength-conversion material 660b according to the design requirement. The wavelength-conversion material 660b is used to provide more optical properties to the two different light-emitting diode (LED) package structures 640a in order to further effectively transfer the light with different wavelengths emitted by the two different light-emitting diode (LED) package structures 640a in the lampshade 650. The wavelength-conversion material 660b may be phosphor or any other suitable material.

It should be appreciated that although the lampshade 650 of the light-emitting diode (LED) light bulb 600 has only one second concave portion 650a in FIG. 4, the number of the concave portion and the optical glue formed therein may be increased according to the actual requirement.

The present disclosure designs at least one concave portion on the lampshade in the light-emitting diode (LED) light bulb and fills the concave portion with the optical glue containing the scattering particle. The light with different wavelengths emitted by the light-emitting diode (LED) package structures having different wavelength may be pre-mixed uniformly in the lampshade through the optical properties of the optical glue and the scattering particle to eliminate the chromatic aberration problems or the non-uniformity of light mixing. The present disclosure further adds the wavelength-conversion material into the optical glue to effectively transfer the light with different wavelengths emitted by the light-emitting diode chips in order to make the light emitted by the light-emitting diode (LED) light bulb closer to the desired color without chromatic aberration.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A light-emitting diode (LED) package structure, comprising:
a lead frame;
at least two light-emitting diode chips having different light-emitting wavelengths disposed on the lead frame;
an encapsulant disposed over the lead frame and covering the light-emitting diode chips, wherein the encapsulant has a first concave portion; and
an optical glue disposed in the first concave portion, wherein the optical glue has a plurality of scattering particles to uniformly mix the lights of different wavelengths emitted by the light-emitting diode chips.

2. The light-emitting diode (LED) package structure as claimed in claim 1, further comprises a main body covering the lead frame, and the main body has a cavity recessed inward, wherein a bottom of the cavity exposes a portion of the lead frame to define a die-mount region, the light-emitting diode chips are fixed in the die-mount region, and the encapsulant is filled in the cavity and covers the light-emitting diode chips.

3. The light-emitting diode (LED) package structure as claimed in claim 2, wherein the first concave portion is formed by compression molding or mechanical processing.

4. The light-emitting diode (LED) package structure as claimed in claim 3, wherein the first concave portion comprises a plurality of concave structures recessed into a surface of the encapsulant.

5. The light-emitting diode (LED) package structure as claimed in claim 4, wherein the plurality of concave structures are arranged periodically.

6. The light-emitting diode (LED) package structure as claimed in claim 3, wherein a concentration of the plurality of scattering particles is 5 vol % to 60 vol %.

7. The light-emitting diode (LED) package structure as claimed in claim 6, wherein the encapsulant further comprises a wavelength-conversion material.

8. The light-emitting diode (LED) package structure as claimed in claim 7, wherein the wavelength-conversion material is phosphor.

9. The light-emitting diode (LED) package structure as claimed in claim 3, wherein the at least two light-emitting diode chips having different light-emitting wavelengths are selected from two or all of red light-emitting diode chips, blue light-emitting diode chips, and green light-emitting diode chips.

10. A light-emitting diode (LED) light bulb, comprising:
a lamp base;
a light source module disposed over the lamp base, wherein the light source module comprises a light-emitting diode (LED) package structure, comprising:
a lead frame;
at least two light-emitting diode chips having different light-emitting wavelengths disposed on the lead frame;
an encapsulant disposed over the lead frame and covering the light-emitting diode chips, wherein the encapsulant has a first concave portion; and
a first optical glue disposed in the first concave portion, wherein the first optical glue has a plurality of first scattering particles to uniformly mix the lights of different wavelengths emitted by the light-emitting diode chips;
a driving circuit disposed in the lamp base and electrically connecting the light source module; and
a lampshade disposed over the lamp base and covering the light source module.

11. The light-emitting diode (LED) light bulb as claimed in claim 10, wherein the light-emitting diode (LED) package structure further comprises a main body covering the lead frame, and the main body has a cavity recessed inward, wherein a bottom of the cavity exposes a portion of the lead frame to define a die-mount region, the light-emitting diode chips are fixed in the die-mount region, and the encapsulant is filled in the cavity and covers the light-emitting diode chips.

12. The light-emitting diode (LED) light bulb as claimed in claim 11, wherein the first concave portion is formed by compression molding or mechanical processing.

13. The light-emitting diode (LED) light bulb as claimed in claim 12, wherein the first concave portion comprises a plurality of concave structures recessed into a surface of the encapsulant.

14. The light-emitting diode (LED) light bulb as claimed in claim 13, wherein the plurality of concave structures are arranged periodically.

15. The light-emitting diode (LED) light bulb as claimed in claim 12, wherein a concentration of the plurality of first scattering particles is 5 vol % to 60 vol %.

16. The light-emitting diode (LED) light bulb as claimed in claim 15, wherein the encapsulant further comprises a wavelength-conversion material.

17. The light-emitting diode (LED) light bulb as claimed in claim 16, wherein the wavelength-conversion material is phosphor.

18. The light-emitting diode (LED) light bulb as claimed in claim 12, wherein the at least two light-emitting diode chips having different light-emitting wavelengths are selected from two or all of red light-emitting diode chips, blue light-emitting diode chips, and green light-emitting diode chips.

19. The light-emitting diode (LED) light bulb as claimed in claim 12, wherein the lampshade comprises:
a second concave portion formed at a top portion of the lampshade; and
a second optical glue disposed in the second concave portion to uniformly mix the lights of different wavelengths emitted by the light-emitting diode chips, wherein the second optical glue has a plurality of second scattering particles.

20. The light-emitting diode (LED) light bulb as claimed in claim 19, wherein a concentration of the plurality of second scattering particles is 5 vol % to 60 vol %, and the plurality of second scattering particles further comprises a wavelength-conversion material.
